(19) United States
(12) Patent Application Publication
(10) Pub. No.: US 2010/0110625 A1
(43) Pub. Date: May 6, 2010

(54) FOLDABLE MOBILE COMPUTING DEVICE AND OPERATING METHOD OF THE SAME

(75) Inventor: YUNG-HSIANG CHEN, Taipei (TW)

Correspondence Address: WPAT, PC;INTELLECTUAL PROPERTY ATTORNEYS, 7225 BEVERLY ST., ANNANDALE, VA, 22003, US

(73) Assignee: ASUSTeK COMPUTER INC., Taipei (TW)

(21) Appl. No.: 12/582,989

(22) Filed: Oct. 21, 2009

(30) Foreign Application Priority Data
Oct. 31, 2008 (TW) 097142040

(51) Int. Cl. H05K 5/00

(52) U.S. Cl. 361/679.02

(57) ABSTRACT

A foldable mobile computing device and the operating method are disclosed, wherein the foldable mobile computing device comprises a first main-body, a second main-body and a pivotal axis. The first main-body has a first surface with a display unit mounted thereon and a second surface; the second main-body has a fourth surface and a third surface having a touch interface set thereon functioning as a keyboard when the foldable mobile computing device is operated with a keyboard input paradigm; and the pivot axis couples the first main-body and the second main-body. When the second surface and the fourth surface are clapped together, the foldable mobile computing device is operated with a non-keyboard input paradigm; and when the first surface and the third surface are driven to form an angle values in a certain range, the non-keyboard input paradigm is shifted to the keyboard input paradigm.

### FIELD OF THE INVENTION

The present invention relates to a foldable mobile computing device and the operating method thereof, and more particularly, to a foldable mobile computing device having an input device, and the operating method thereof.

### BACKGROUND OF THE INVENTION

As the development of digital technology, many kinds of mobile computing device, such as cell phones, mobile phones, personal digital assistants (PDA), digital video players, digital book readers or notebooks (laptop computers), have been provided to improve the modern life. To provide more portable convenience, entertainment and users' willingness to use, these electronic devices are typically designed as slim-thin and light as possible for allowing the users operating at any time and at any place as he/she like.

However, this approach (design) has its drawbacks. Hence a mobile computing device designed as slim and thin means that there has no sufficient volume available for its operating interface, thus the operating environment of the mobile computing device may be limited, and this may result in difficulties for data inputting and operation. For instance, a cell phone typically can be designed in a slide type or in a flip-flop type, wherein different type of cell phone has different operating interface. Referring to FIGS. 1A and 1B, FIGS. 1A and 1B illustrate construction profiles of a slide cell phone 10 in accordance with the prior art. As depicted in FIG. 1A, the operating condition of slide cell phone 10 is kept in standby condition or operated with a non-keyboard input paradigm (wherein, there appears no keyboard). When a user wants to operate the keyboard, he/she should drive the upper main-body 11 sliding against the lower main-body 13 beneath the upper main-body 11 to expose the keyboard, whereby the operating condition of the slide cell phone 10 is shifted to a keyboard input paradigm, as depicted in FIG. 1B. In this prior art exemplar, the upper main-body 11 of the slide cell phone 10 has a display unit 100 and an operating interface 12. And a means for sliding and connecting is disposed to structurally and electrically couple the upper main-body 11 to the lower main-body 13. In this approach, however, since the surface of the lower main-body 13 on which an operating interface 14 is disposed, in a certain extent, is partially covered by the upper main-body 11, thus the space provided for the operating interface 14 may be limited. Such that the operation of the slide cell phone 10 may be retarded, and there exists some functions that can not be completed with the absence of either the operating interface 12 or the operating interface 14. Besides, because of the structurally limitations, that the display unit 100 of the upper main-body 11 is parallel to the operating interface 12 and the operating interface 14, the display unit 100 can not be flipped up, like a flip-flop cell phone, to select a angle in respect to the operating interface 12 suitable for operation.

FIGS. 2A and 2B illustrate construction profiles of a flip-flop cell phone 20 in accordance with the prior art. As depicted in FIG. 2A, the flip-flop cell phone 20 is kept in standby condition. When a user wants to perform the procedures of call origination or termination or even wants to operate the keyboard, he/she should drive an upper main-body 21 to pivot around a pivotal axis 25 coupling the upper main-body 21 on the lower main-body 23 to expose the keyboard, as depicted in FIG. 2B. In comparison with the slide cell phone 10, the flip-flop cell phone 20 can provide more space for its operating interface 24 disposed on the lower main-body 23. However, when the flip-flop cell phone 20 is kept in standby condition, the upper-main-body 21 and the lower main-body 23 are clapped together, whereby a display unit 200 disposed on the inner surface of the upper main-body 21 should be closed. Thus it is necessary to provide an additional sub-display 201 disposed on the outer surfaces of the upper main-body 21 allowing the users to observe the current performance of the flip-flop cell phone 20. Though the sub-display 201 may provide the user operation convenience, nevertheless, it should cost certain additional expenditures.

Foregoing design concepts has been applied to the other mobile computing devices to purchase their optimum performance. For example, notebooks generally adopt a flip cover design to purchase greater operating interface, whereby a full-size or standard keyboard can be disposed on its main-body to provide their users a comfortable operating interface. Otherwise, some other mobile computing devices, such as PDAs, Smart-Phones or pocket personal computers, adopt slide cover design to purchase slim-thin and light. Thus in some prior art exemplars, an integrated keyboard is applied to these PDAs, Smart-Phones or pocket personal computers, by which though some strokes have to be eliminated, nevertheless the major functions as provided by a standard are still retained. However, the operating comfort and convenience should be decline. In short, the current requirements of a mobile computing device for satisfying the users are not only providing the advantages of light and portability but also providing an easily inputting operating interface, such as a standard keyboard with complete strikes or buttons, and a convenient display for accommodating the users observing the computing results.

### SUMMARY OF THE INVENTION

One aspect of the present invention, a foldable mobile computing device is disclosed. The foldable mobile computing device comprises a first main-body, a second main-body and a pivotal axis. The first main-body has a first surface and a second surface, wherein the first surface has a display unit mounted thereon for displaying and manipulating a controlling image; the second main-body has a third surface and a fourth surface, wherein the third surface has a touch interface set thereon functioning as a keyboard when the foldable mobile computing device is operated with a keyboard input paradigm; and the pivot axis couples the first main-body and the second main-body. When the second surface and the fourth surface are clapped together, the foldable mobile computing device is operated with a non-keyboard input paradigm; and when the first surface and the third surface are driven to form an angle values in a certain range, the non-keyboard input paradigm is shifted to the keyboard input paradigm.

Another aspect of the present invention, a method for operating a foldable mobile computing device is disclosed, wherein the foldable mobile computing device comprises a pivot axis used to couple a first main-body and a second main-body; the first main-body has a first surface and a second surface parallel to the first surface; and the second main-body has a third surface and a fourth surface parallel to the third surface. The operating method comprises steps as follows: when the first main-body and the second main-body are clapped together to force the second surface parallel clapping on the fourth surface, the foldable mobile computing device can be operated with a non-keyboard input paradigm. When at least one of the first main-body and the second main-body is driven to pivot around the pivot axis, so as to force a display unit mounted on the first surface and a touch panel disposed on the third surface forming an angle values in a certain range, the non-keyboard input paradigm can be shifted to a keyboard input paradigm.

In accordance with the embodiments of the present invention, a foldable mobile computing device and the operating method thereof are disclosed, wherein the foldable mobile computing device has two main-bodies coupled by a pivot axis. When the foldable mobile computing device is folded up, the operation condition of the foldable mobile computing device can be kept on a non-keyboard input paradigm, and when one of the main-bodies is pivot around the pivot axis to form the angle between these two main-bodies values in a certain range, the operation condition of the foldable mobile computing device can be shifted from a keyboard input paradigm to a non-keyboard input paradigm.

### BRIEF DESCRIPTION OF THE DRAWINGS

The above objects and advantages of the present invention will become more readily apparent to those ordinarily skilled in the art after reviewing the following detailed description and the accompanying drawings, in which:

FIGS. 1A and B illustrate construction profiles of a slide cell phone in accordance with the prior art.

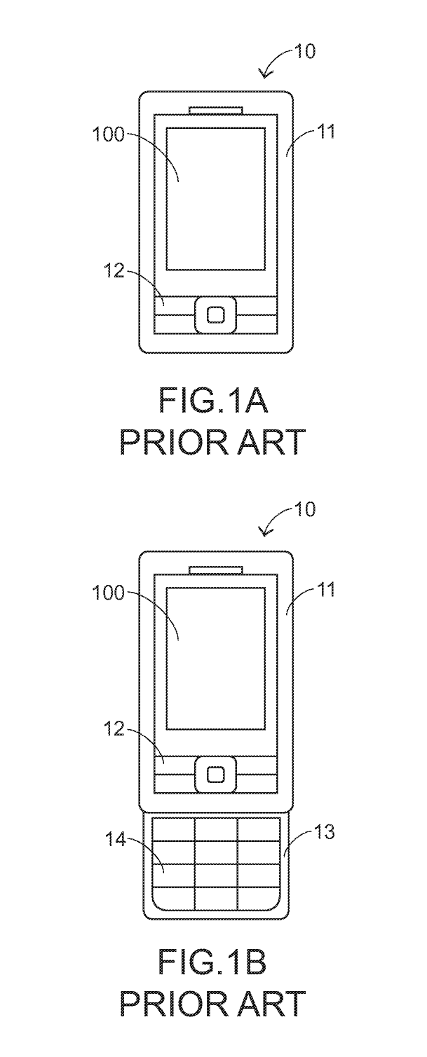

FIGS. 2A and B illustrate construction profiles of a flip-flop cell phone in accordance with the prior art.

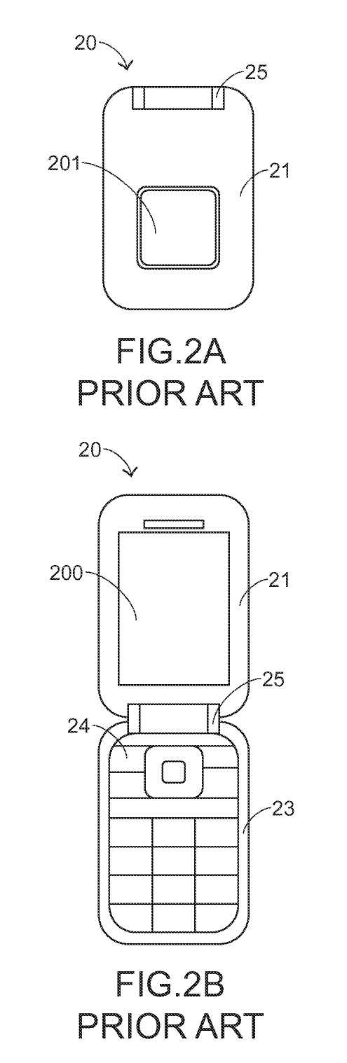

FIGS. 3A to C illustrate construction profiles of a foldable mobile computing device which is kept in a folded-up condition in accordance with one embodiment of the present invention.

FIGS. 4A and B illustrate construction profiles of a foldable mobile computing device which is kept in a flip-up condition in accordance with one embodiment of the present invention.

### DETAILED DESCRIPTION OF PREFERRED EMBODIMENTS

To illustrate the make and use of the present invention, there provides several embodiments of foldable mobile computing devices to discuss. Of note that each of the foldable mobile computing devices has two main-bodies pivot coupled with each other by a axis allowing main-bodies to rotate around, whereby the structural profiles of the foldable mobile computing devices provided by the present embodiments may similar to the prior art foldable mobile computing devices, such as the aforementioned prior art flip-flop cell phone. Though the profiles of the present embodiments are similar to the prior art, there are nevertheless characteristics, wherein a pivot axis disposed on the outer edge of two main-bodies of the foldable mobile computing device is used to manipulate the inputting paradigm of the foldable mobile computing devices according to the pivotal angle formed between the two main-bodies.

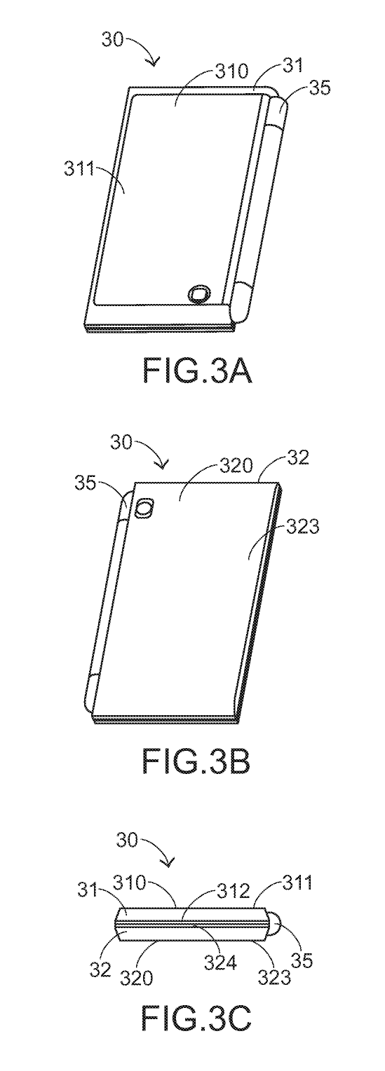

FIGS. 3A to 3C illustrate construction profiles of a foldable mobile computing device 30 which is kept in a folded-up condition in accordance with one embodiment of the present invention, wherein FIG. 3A is the front view of the foldable mobile computing device 30; FIG. 3B is the rear view of the foldable mobile computing device 30; and FIG. 3C is the side view of the foldable mobile computing device 30. As depicted in FIGS. 3A to 3C, the foldable mobile computing device 30 comprises a first main-body 31, a second main-body 32 and a pivot axis 35, wherein the pivot axis 35 is used to couple the first main-body 31 on the second main-body 32, whereby the first main-body 31 and the second main-body 32 can rotate there around. Each of the first main-body 31 and the second main-body 32 comprises two surfaces. For example, the first main-body 31 has a first surface 311 and a second surface 312 parallel to the first surface 311; and the second main-body 32 has a third surface 323 and a fourth surface 324 parallel to the third surface 323. When the foldable mobile computing device 30 is kept in a folded-up condition, the first surface 311 and the third surface 323 are disposed on opposite side serve as the external surfaces of the foldable mobile computing device 30; the second surface 312 and the fourth surface 324 are clapped together and folded in the foldable mobile computing device 30.

The foldable mobile computing device 30 further comprises an operation system which is constructed by various integrating circuit and processing units disposed in the first main-body 31 or the second main-body 32 designed according to the functional requirements and the intended use of the foldable mobile computing device 30. In the embodiments of the present invention, a display unit 310 used to display controlling images for performing the operation system is disposed on the first surface 311 of the first main-body 31. In the preferred embodiments, the preferable display unit 310 may be constructed by a touch panel. A touch interface 320 is disposed on the third surface 323 of the second main-body 32. In the preferred embodiments, the touch interface 320 may be constructed by a touch panel and/or a touch keypad.

Continued from the preceding description, the operating method of the foldable mobile computing device 30 can be set forth as follows: When the first main-body 31 and the second main-body 32 are clapped together, the second surface 312 is forced to clap on the fourth surface 324; meanwhile the second surface 312, the third surface 323 and the fourth surface 324 are parallel to the first surface 311; the foldable mobile computing device can be operated with a non-keyboard input paradigm. In this operating condition the touch interface 320 embodying as a touch panel or a touch keypad is not displayed on the third surface 323. In other words, Because the touch interface 320 is embodied as a plurality of functional strikes displayed on a touch panel and/or a touch keypad, each of which is associated with a predetermined function to allow the users control the aforementioned operation system, when the touch interface 320 can not be displayed on the third surface 323, the predetermined functions in corresponding to the functional strikes are not available.

In some embodiments of the present invention, the pivot axis 35 is designed as a single axis allowing the first main-body 31 or the second main-body 32 to rotate there around to form a rotating angle values in a certain range, such that an angle formed between the first main-body 31 and the second main-body 32 can be substantially less than 360 degree. In some preferred embodiments, the pivot axis 35 further provides a fixing function to retain the relative position between the first main-body 31 and the second main-body 32 or the relative position of the first main-body 31 and the second main-body 32 in respect to the pivot axis 35, so as to keep the angle formed by the first main-body 31 and the second main-body 32 in a constant degree during the rotation of the first main-body 31 and the second main-body 32. Hence the structure and functions of the single-axis pivot axis are well known in the prior art, hereafter it is not necessary to describe in detail.

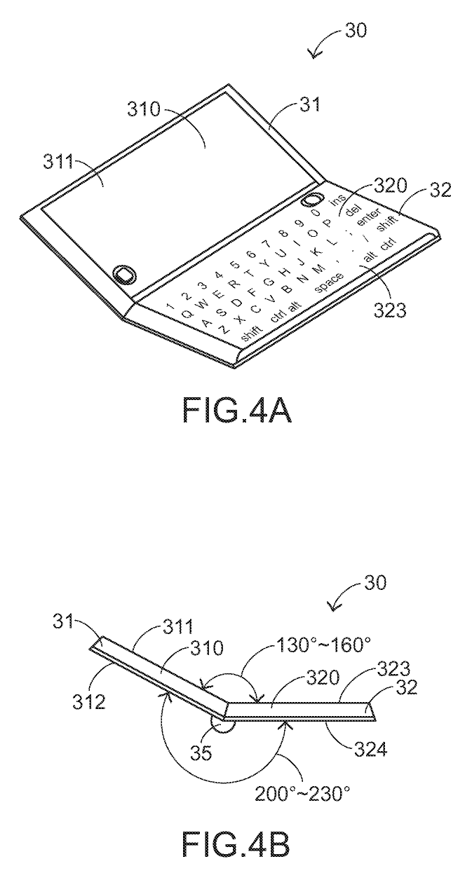

FIGS. 4A and 4B illustrate construction profiles of a foldable mobile computing device 30 which is kept in a flip-up condition in accordance with one embodiment of the present invention, wherein FIG. 4A is the perspective view of the foldable mobile computing device 30; and FIG. 4B is the side view of the foldable mobile computing device 30. When the first main-body 31 or the second main-body 32 rotates around the pivot axis 35, the foldable mobile computing device 30 can be shifted from the folded up condition shown in the FIGS. 3A to C to the flip-up condition As depicted in FIGS. 4A and 4B. Meanwhile the operating condition of the foldable mobile computing device 30 can be shift from the standby condition or the non-keyboard input paradigm to a keyboard input paradigm. In some embodiments for operating the foldable mobile computing device 30, the angle formed by the first main-body 31 and the second main-body 32 should be kept in a range from about 200 to 230 degrees during the rotation of the first main-body 31 and the second main-body 32. At the same time the parallel first surface 311 and the third surface 323 can also be shifted to form an angle ranges from about 130 to 160 degrees. Such that the display unit 310 disposed on the first surface 311 of the first main-body 31 and the touch interface 320 disposed on the third surface 323 of the second main-body 32 are retained in a proper relative position suitable for the users to manipulate and observe the controlling images shown on the display unit 310 of the foldable mobile computing device 30.

When the operating condition of the foldable mobile computing device 30 is operated with a keyboard input paradigm, the touch interface 320 is displayed on the third surface 323. Namely the functional strikes of the touch interface 320 in corresponding to the predetermined functions can be available to allow the users control the aforementioned operation system. As depicted in FIG. 4A, the touch interface 320 is embodied as a plurality of functional strokes that can be associated as a keyboard. And, in some preferred embodiments of the present invention, the functional strokes of the touch interface 320 may be associated as a full sized keyboard, a standard keyboard or an operating interface with eliminating strokes but still remains the major functions as provided by a standard keyboard. When the users compress the functional strokes displayed on the touch panel or the touch keypad to manipulate the touch interface 320, the controlling images or the operation process of the foldable mobile computing devices 30 can be displayed by the display unit 310.

In some embodiments of the present invention, the preferred method for shifting the operating condition of the foldable mobile computing device 30 from the standby condition or the non-keyboard input paradigm to a keyboard input paradigm is to rotate the first main-body 31 or the second main-body 32 that are originally clapped up together to the condition shown as FIG. 4B. Wherein a sensor can be further disposed on the pivot axis 35 to detect the rating angle of the first main-body 31 or the second main-body 32. Hence the structure and functions of the sensor disposed on a pivot axis are well known in the prior art, hereafter it is not necessary to describe in detail.

In other words, when the second surface 312 and the fourth surface 324 that are originally clasped up to gather are separated by the rotation of the first main-body 31 or the second main-body 32, the foldable mobile computing device 30 no longer retains in the standby condition, and the functional strokes of the touch interface 320 can be displayed and available for operation. The preferred condition for operating the touch interface 320 is keep the first main-body 31 and the second main-body 32 in a certain relative position, wherein the outer surfaces of the first main-body 31 and the second main-body 32 (the second surface 312 and the fourth surface 324) may form an angle ranges from about 200 to 230 degrees. Namely (in accordance with FIG. 4B), when the first surface 311 and the third surface 323 are shifted to form an angle ranging from about 130 to 160 degrees, the touch interface 320 can be manipulated more easy and comfortable. Otherwise, when the first main-body 31 or the second main-body 32 rotates reversely around the pivot axis 35, the foldable mobile computing device 30 can be shifted from the flip-up condition shown in the FIGS. 4A and B to the folded-up condition as depicted in FIGS. 3A to C; the operating condition of the foldable mobile computing device 30 can also be shifted from the keyboard input paradigm to the standby condition or the non-keyboard input paradigm again; and the angle formed between the first surface 311 and the third surface 323 can be shift back to zero.

It must be appreciated that the aforementioned concepts cane be applied to other mobile computing devices. Thus the foldable mobile computing device 30 can be a cell phone, a mobile phone, a personal PDA, a digital video player, a digital book reader, a notebook or any kind of portable electronic device.

The design of the present foldable mobile computing device 30 that has a foldable first main-body 31 and a second main-body 32 is characterized by the concepts as follows: Wherein a display unit 310 is disposed on one of the outer surface of the foldable mobile computing device 30, the first surface 311 of the first main-body 31 that can be rotated around a pivot axis 35. By rotating the first main-body 31 in a direction reverse to what the conventional flip-flop mobile computing devices do, the operating condition of the foldable mobile computing device 30 can be shifted, i.e. from a keyboard input paradigm to a non-keyboard input paradigm. Since the display unit 310 is dispose on the outer surface of the foldable mobile computing device 30, no matter how the operating condition is shifted, the display unit 310 can perform in either keyboard input paradigm or non-keyboard input paradigm. Thus the display unit 310 of the present invention is compatible to provide the functions that are conventionally completed by a display unit and a sub-display unit of a prior art flip-flop mobile computing device 20. Namely, mere the present display unit 310 can provide the functions equivalent to that provided by the combination of the display unit and the sub-display unit of the conventional flip-flop mobile computing device 20. Such that the sub-display unit is no longer necessary for the foldable mobile computing device 30. Accordingly, this approach of the present invention not only can reduce the manufacturing cost of a foldable mobile computing device, but also can entertain the users by virtue of the always-available display unit 310.

Besides, because of when the first main-body 31 and the second main-body 32 are clapped together, the operation condition of the foldable mobile computing device 30 has been shifted to the non-keyboard input paradigm and kept in standby condition, thus the functional strikes of the touch interface 320 used to manipulate the foldable mobile computing device 30 cannot be displayed and enabled. Though the touch interface 320 is disposed on the other outer surface of the foldable mobile computing device 30, nevertheless, it should not be interfered by users' touch or external compression. Such that when the foldable mobile computing device 30 is carried or held by a user, an unexpected command should not be inputted through the touch interface 320. In accordance with the preferred embodiment shown on FIG. 4A, the touch interface 320 set on the second main-body 32 is displayed as a standard keyboard. In comparison with the conventional design of a slide cell phone 10, since the upper main-body 11 partially covers the surface of the lower main-body 13 on which the operating interface 14 of the slide cell phone 10 is disposed, the space provided for the operating interface 14 may be limited. In contrast, since the first main-body 31 and the second main-body 32 are coupled by a pivot axis, the third surface 323 of second main-body 32 on which the touch interface 320 is disposed should not be covered or interfered by other spare parts of the foldable mobile computing device 30. Accordingly, the operating space for setting the touch interface 320 should not be limited, whereby the users can comfortably use the touch interface 320 as a standard keyboard to input or operate the foldable mobile computing device 30.

In accordance with the aforementioned description, the foldable mobile computing device provided by the present invention not only can resolve the aforementioned prior art problems but also can provide more portable and operating convenience allowing the users to observe the performance of the foldable mobile computing device at any time. Furthermore, the manufacturing cost of the foldable mobile computing device is decreased and the users' willingness to use can be increased by virtue of the applications of the present invention.

As is understood by a person skilled in the art, it is intended to cover various modifications and similar arrangements included within the spirit and scope of the appended claims, the scope of which should be accorded the broadest interpretation so as to encompass all such modifications and similar structure.

What is claimed is:

1. A foldable mobile computing device comprising:
a first main-body, having a first surface and a second surface, wherein the first surface has a display unit mounted thereon for displaying or manipulating a controlling image;
a second main-body, having a third surface and a fourth surface, wherein the third surface has a touch interface set thereon functioning as a keyboard when the foldable mobile computing device is operated with a keyboard input paradigm; and
a pivotal axis, coupling the first main-body and the second main-body;
when the second surface and the fourth surface are clapped together, the foldable mobile computing device is operated with a non-keyboard input paradigm; and when the first surface and the third surface are driven to form an angle values in a certain range, the non-keyboard input paradigm is then shifted to the keyboard input paradigm.

2. The foldable mobile computing device according to claim 1, wherein when at least one of the first main-body and the second main-body pivots around the pivotal axis to force the first surface and the third surface which are originally parallel with each other to form the angle, the non-keyboard input paradigm can be shifted to the keyboard input paradigm.

3. The foldable mobile computing device according to claim 1, wherein the touch interface is a touch panel or a touch keypad with a plurality of functional strokes.

4. The foldable mobile computing device according to claim 3, wherein when the non-keyboard input paradigm becomes available, the touch interface is turn off and the functional strokes can not be displayed;
otherwise when the keyboard input paradigm becomes available, the touch interface is turn on and the functional strokes are displayed.

5. The foldable mobile computing device according to claim 4, wherein the functional strokes displayed by the touch interface can be associated as a full size keyboard, a standard keyboard or an operating interface with major functions as provided by the standard keyboard.

6. The foldable mobile computing device according to claim 1, wherein the controlling image can be displayed on the display unit as the foldable mobile computing device is operated with the non-keyboard input paradigm.

7. The foldable mobile computing device according to claim 1, wherein the angle ranges from about 130 to 160 degree.

8. The foldable mobile computing device according to claim 1, wherein the display unit is a touch panel.

9. A method for operating a foldable mobile computing device that comprises a pivot axis used to couple a first main-body and a second main-body comprising:
clapping the first main-body and the second main-body together to shift the foldable mobile computing device operated with a non-keyboard input paradigm; and
pivoting at least one of the first main-body and the second main-body around the pivot axis to form an angle between the first main-body and the second main-body values in a certain range to shift the non-keyboard input paradigm to a keyboard input paradigm.

10. The operating method according to claim 9, wherein the angle ranges from about 130 to 160 degree.
